(19) United States
(12) Patent Application Publication
(10) Pub. No.: US 2020/0165727 A1
(43) Pub. Date: May 28, 2020

(54) 1-Methyl-1-Iso-Propoxy-Silacycloalkanes And Dense Organosilica Films Made Therefrom

(71) Applicant: Versum Materials US, LLC, Tempe, AZ (US)

(72) Inventors: William Robert Entley, Gilbert, AZ (US); Jennifer Lynn Anne Achtyl, Chandler, AZ (US); Raymond Nicholas Vrtis, Carefree, AZ (US); Robert Gordon Ridgeway, Chandler, AZ (US); Xinjian Lei, Vista, CA (US)

(73) Assignee: Versum Materials US, LLC, Tempe, AZ (US)

(21) Appl. No.: 16/695,676

(22) Filed: Nov. 26, 2019

Related U.S. Application Data
(60) Provisional application No. 62/771,933, filed on Nov. 27, 2018.
(60) Provisional application No. 62/878,850, filed on Jul. 26, 2019.

(51) Int. Cl. C23C 16/50; C03C 17/30

(52) U.S. Cl. CPC C23C 16/50; C03C 2218/153; C03C 17/30

(57) ABSTRACT

A method for making a dense organosilicon film with improved mechanical properties, the method comprising the steps of: providing a substrate within a reaction chamber; introducing into the reaction chamber a gaseous composition comprising 1-methyl-1-iso-propoxy-silacyclopentane or 1-methyl-1-iso-propoxy-silacyclobutane; and applying energy to the gaseous composition comprising 1-methyl-1-iso-propoxy-silacyclopentane or 1-methyl-1-iso-propoxy-silacyclobutane in the reaction chamber to induce reaction of the gaseous composition comprising 1-methyl-1-iso-propoxy-silacyclopentane or 1-methyl-1-iso-propoxy-silacyclobutane to deposit an organosilicon film on the substrate, wherein the organosilicon film has a dielectric constant of from 2.70 to 3.20, an elastic modulus of from 11 to 25 GPa, and an at. % carbon of from 12 to 31 as measured by XPS.

### CROSS-REFERENCE TO RELATED APPLICATIONS

This patent application is a non-provisional of U.S. provisional patent application Ser. No. 62/771,933, filed on Nov. 27, 2018, and provisional patent application Ser. No. 62/878,850, filed Jul. 26, 2019, which is incorporated herein by reference in its entirety.

### BACKGROUND OF THE INVENTION

Described herein is a composition and method for formation of a dense organosilica dielectric film using 1-methyl-1-iso-propoxy-silacycloalknane selected from the group consisting of 1-methyl-1-iso-propoxy-silacyclopentane and 1-methyl-1-iso-propoxy-silacyclobutane as a precursor to the film. More specifically, described herein is a composition and plasma enhanced chemical vapor deposition (PECVD) method for forming a dense film having a dielectric constant, k≥2.7, wherein the film has a high elastic modulus and excellent resistance to plasma induced damage as compared to films made from conventional precursors.

The electronics industry utilizes dielectric materials as insulating layers between circuits and components of integrated circuits (IC) and associated electronic devices. Line dimensions are being reduced in order to increase the speed and memory storage capability of microelectronic devices (e.g., computer chips). As the line dimensions decrease, the insulating requirements for the interlayer dielectric (ILD) become much more rigorous. Shrinking the spacing requires a lower dielectric constant to minimize the RC time constant, where R is the resistance of the conductive line and C is the capacitance of the insulating dielectric interlayer. Capacitance (C) is inversely proportional to spacing and proportional to the dielectric constant (k) of the interlayer dielectric (ILD). Conventional silica (SiO₂) CVD dielectric films produced from SiH₄ or TEOS (Si(OCH₂CH₃)₄, tetraethylorthosilicate) and O₂ have a dielectric constant k greater than 4.0. There are several ways in which industry has attempted to produce silica-based CVD films with lower dielectric constants, the most successful being the doping of the insulating silicon oxide film with organic groups providing dielectric constants ranging from about 2.7 to about 3.5. This organosilica glass is typically deposited as a dense film (density ˜1.5 g/cm³) from an organosilicon precursor, such as a methylsilane or siloxane, and an oxidant, such as O₂ or N₂O. Organosilica glass will be herein be referred to as OSG.

Plasma or process induced damage (PID) in low k films is caused by the removal of carbon from the film during plasma exposure, particularly during etch and photoresist strip processes. This changes the plasma damaged region from hydrophobic to hydrophilic. Exposure of the hydrophilic SiO₂-like damaged layer to dilute HF-based wet chemical post plasma treatments (with or without additives such as surfactants) results in rapid dissolution of this layer. In patterned low k wafers, this results in profile erosion. Process induced damage and the resulting profile erosion in low k films is a significant problem that device manufacturers must overcome when integrating low k materials in a ULSI interconnect.

Films with increased mechanical properties (higher elastic modulus, higher hardness) reduce line edge roughness in patterned features, reduce pattern collapse, and provide greater internal mechanical stress within an interconnect, reducing failures due to electromigration. Thus, there is a need for low k films with excellent resistance to PID and the highest possible mechanical properties at a given dielectric constant.

### BRIEF SUMMARY OF THE INVENTION

The method and composition described herein fulfill one or more needs described above. The 1-methyl-1-iso-propoxy-silacyclopentane and/or 1-methyl-1-iso-propoxy-silacyclobutane precursor can be used to deposit dense low k films with k valves between about 2.70 to about 3.20, such films exhibiting an unexpectedly high elastic modulus/hardness, and an unexpectedly high resistance to plasma induced damage.

In one aspect, the disclosure provides a method for making a dense organosilica film with improved mechanical properties, the method comprising the steps of: providing a substrate within a reaction chamber; introducing into the reaction chamber a gaseous composition comprising 1-methyl-1-iso-propoxy-silacyclopentane; and applying energy to the gaseous composition in the reaction chamber to induce reaction of the gaseous composition and thereby deposit an organosilicon film on the substrate, wherein the organosilica film has a dielectric constant of from 2.70 to 3.20 and an elastic modulus of from 11 to 25 GPa.

In another aspect, the disclosure provides a method for making a dense organosilica film with improved mechanical properties, the method comprising the steps of: providing a substrate within a reaction chamber; introducing into the reaction chamber a gaseous composition comprising 1-methyl-1-iso-propoxy-silacyclopentane and/or 1-methyl-1-iso-propoxy-silacyclobutane; and applying energy to the gaseous composition in the reaction chamber to induce reaction of the gaseous composition and thereby deposit an organosilica film on the substrate, wherein the organosilica film has a dielectric constant of from 2.70 to 3.2, an elastic modulus of from 11 to 25 GPa, and an at. % carbon of from 12 to 31 as measured by XPS.

### BRIEF DESCRIPTION OF THE DRAWINGS

FIG. 1 is a table summarizing a design of experiment (DOE) strategy to explore the range of dense low k films deposited using 1-methyl-1-iso-propoxy-silacyclopentane (MIPSCP) as a precursor;

FIG. 2 is a table summarizing a design of experiment (DOE) strategy to explore the range of dense low k films deposited using 1-methyl-1-ethoxy-silacyclopentane (MESCP) as a precursor for comparison;

FIG. 3 is a table comparing the physical and mechanical properties of dense low k organosilane films deposited with MIPSCP and MESCP as precursors, wherein both films exhibit a dielectric constant, k, of about 2.90;

FIG. 4 is a table comparing the physical and mechanical properties of dense low k organosilane films deposited with MIPSCP and MESCP as precursors, wherein both films exhibit a dielectric constant, k, of about 3.00; and

FIG. 5 is a graph showing the resistance to plasma induced damage of MIPSCP and MESCP films as measured by thickness loss in dilute HF (300:1) at room temperature for 300 seconds.

### DETAILED DESCRIPTION OF THE INVENTION

Described herein is a chemical vapor deposition method for making a dense organosilica film with improved mechanical properties, the method comprising the steps of: providing a substrate within a reaction chamber; introducing into the reaction chamber a gaseous composition comprising 1-methyl-1-iso-propoxy-silacyclopentane and/or 1-methyl-1-iso-propoxy-silacyclobutane; and applying energy to the gaseous composition comprising 1-methyl-1-iso-propoxy-silacyclopentane and/or 1-methyl-1-iso-propoxy-silacyclobutane in the reaction chamber to induce reaction of the gaseous composition comprising 1-methyl-1-iso-propoxy-silacyclopentane and/or 1-methyl-1-iso-propoxy-silacyclobutane and thereby deposit an organosilica film on the substrate, wherein the organosilica film has a dielectric constant of from 2.70 to 3.20, an elastic modulus of from 11 to 25 GPa, and an at. % carbon of from 12 to 31 as measured by XPS, preferably a dielectric constant of from 2.80 to 3.00, an elastic modulus of from 11 to 18 GPa, and an at. % carbon from 12 to 31 as measured by XPS.

Also described herein is a method for making a dense organosilica film with improved mechanical properties, the method comprising the steps of: providing a substrate within a reaction chamber; introducing into the reaction chamber a gaseous composition comprising 1-methyl-1-iso-propoxy-silacyclopentane and/or 1-methyl-1-iso-propoxy-silacyclobutane; and applying energy to the gaseous composition comprising 1-methyl-1-iso-propoxy-silacyclopentane and/or 1-methyl-1-iso-propoxy-silacyclobutane in the reaction chamber to induce reaction of the gaseous composition comprising 1-methyl-1-iso-propoxy-silacyclopentane and/or 1-methyl-1-iso-propoxy-silacyclobutane to deposit an organosilica film on the substrate, wherein the organosilica film has a dielectric constant of from 2.70 to 3.20 and an elastic modulus of from 11 to 25 GPa.

The 1-methyl-1-iso-propoxy-silacyclopentane and/or 1-methyl-1-iso-propoxy-silacyclobutane provides unique attributes that make it possible to achieve a relatively low dielectric constant for a dense organosilica film and to surprisingly exhibit excellent mechanical properties compared to prior art structure former precursors such as diethoxymethylsilane (DEMS®) and 1-methyl-1-ethoxy-silacyclopentane (MESCAP).

The low k dielectric films are organosilica glass (“OSG”) films or materials. Organosilicates are employed in the electronics industry, for example, as low k materials. Material properties depend upon the chemical composition and structure of the film. Since the type of organosilicon precursor has a strong effect upon the film structure and composition, it is beneficial to use precursors that provide the required film properties to ensure that the addition of the needed amount of porosity to reach the desired dielectric constant does not produce films that are mechanically unsound. The method and composition described herein provides the means to generate low k dielectric films that have a desirable balance of electrical and mechanical properties as well as other beneficial film properties such as high carbon content to provide improved integration plasma resistance.

In certain embodiments of the method and composition described herein, a layer of silicon-containing dielectric material is deposited on at a least a portion of a substrate via a chemical vapor deposition (CVD) process employing a reaction chamber. The method thus includes the step of providing a substrate within a reaction chamber. Suitable substrates include, but are not limited to, semiconductor materials such as gallium arsenide (“GaAs”), silicon, and compositions containing silicon such as crystalline silicon, polysilicon, amorphous silicon, epitaxial silicon, silicon dioxide (“SiO₂”), silicon glass, silicon nitride, fused silica, glass, quartz, borosilicate glass, and combinations thereof. Other suitable materials include chromium, molybdenum, and other metals commonly employed in semi-conductor, integrated circuits, flat panel display, and flexible display applications. The substrate may have additional layers such as, for example, silicon, SiO₂, organosilicate glass (OSG), fluorinated silicate glass (FSG), boron carbonitride, silicon carbide, hydrogenated silicon carbide, silicon nitride, hydrogenated silicon nitride, silicon carbonitride, hydrogenated silicon carbonitride, boronitride, organic-inorganic composite materials, photoresists, organic polymers, porous organic and inorganic materials and composites, metal oxides such as aluminum oxide, and germanium oxide. Still further layers can also be germanosilicates, aluminosilicates, copper and aluminum, and diffusion barrier materials such as, but not limited to, TiN, Ti(C)N, TaN, Ta(C)N, Ta, W, or WN.

The reaction chamber is typically, for example, a thermal CVD or a plasma enhanced CVD reactor or a batch furnace type reactor. In one embodiment, a liquid delivery system may be utilized. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

The method disclosed herein includes the step of introducing into the reaction chamber a gaseous composition comprising 1-methyl-1-iso-propoxy-silacyclopentane and/or 1-methyl-1-iso-propoxy-silacyclobutane. In some embodiments, the composition may include additional reactants such as, for example, oxygen-containing species such as, for example, O₂, O₃, and N₂O, gaseous or liquid organic substances, CO₂, or CO. In one particular embodiment, the reaction mixture introduced into the reaction chamber comprises the at least one oxidant selected from the group consisting of O₂, N₂O, NO, NO₂, CO₂, water, H₂O₂, ozone, and combinations thereof. In an alternative embodiment, the reaction mixture does not comprise an oxidant.

The composition for depositing the dielectric film described herein comprises from about 50 to about 100 weight percent of 1-methyl-1-iso-propoxy-silacyclopentane and/or 1-methyl-1 -iso-propoxy-silacyclobutane.

In embodiments, the gaseous composition comprising 1-methyl-1-iso-propoxy-silacyclopentane and/or 1-methyl-1-iso-propoxy-silacyclobutane is substantially free of or free of additives such as, for example, hardening additives.

In embodiments, the gaseous composition comprising 1-methyl-1-iso-propoxy-silacyclopentane and/or 1-methyl-1-iso-propoxy-silacyclobutane is substantially free of or free of halides such as, for example, chlorides.

In addition to the 1-methyl-1-iso-propoxy-silacyclopentane and/or 1-methyl-1-iso-propoxy-silacyclobutane, additional materials can be introduced into the reaction chamber prior to, during and/or after the deposition reaction. Such materials include, e.g., inert gas (e.g., He, Ar, N₂, Kr, Xe, etc.), which may be employed as a carrier gas for lesser volatile precursors and/or which can promote the curing of the as-deposited materials and provide a more stable final film.

Any reagent employed, including the 1-methyl-1-iso-propoxy-silacyclopentane and/or 1-methyl-1-iso-propoxy-silacyclobutane can be carried into the reactor separately from distinct sources or as a mixture. The reagents can be delivered to the reactor system by any number of means, preferably using a pressurizable stainless steel vessel fitted with the proper valves and fittings to allow the delivery of liquid to the reaction chamber. Preferably, the precursor is delivered into the reaction chamber as a gas, that is, the liquid must be vaporized before it is delivered into the reaction chamber.

The method disclosed herein includes the step of applying energy to the gaseous composition comprising 1-methyl-1-iso-propoxy-silacyclopentane and/or 1-methyl-1-iso-propoxy-silacyclobutane in the reaction chamber to induce reaction of the gaseous composition comprising 1-methyl-1-iso-propoxy-silacyclopentane and/or 1-methyl-1-iso-propoxy-silacyclobutane to deposit an organosilica film on the substrate, wherein the organosilica film has a dielectric constant of from 2.70 to 3.20 in some embodiments, 2.70 to 3.00 in other embodiments, and 2.80 to 3.00 in still preferred embodiments, an elastic modulus of from 11 to 25 GPa, preferably from 11 to 18 GPa, and an at. % carbon of from 12 to 31 as measured by XPS. In one embodiment, the organosilica film has a dielectric constant of about 3.2, an elastic modulus of about 25 GPa, and an at. % carbon of about 14 as measured by XPS. Energy is applied to the gaseous reagents to induce the 1-methyl-1-iso-propoxy-silacyclopentane and/or 1-methyl-1-iso-propoxy-silacyclobutane and other reactants, if present, to react and to form the film on the substrate. Such energy can be provided by, e.g., plasma, pulsed plasma, helicon plasma, high density plasma, capacitively coupled plasma, inductively coupled plasma, remote plasma, hot filament, and thermal (i.e., non-filament) methods. A secondary rf frequency source can be used to modify the plasma characteristics at the substrate surface. Preferably, the film is formed by plasma enhanced chemical vapor deposition (“PECVD”).

The flow rate for each of the gaseous reagents preferably ranges from 10 to 5000 sccm, more preferably from 30 to 1000 sccm, per single 300 mm wafer. The individual rates are selected in order to provide the desired amounts of structure-forming agent in the film. The actual flow rates needed may depend upon wafer size and chamber configuration and are in no way limited to 300 mm wafers or single wafer chambers.

In certain embodiments, the film is deposited at a deposition rate of from about 41 to 80 nanometers (nm) per minute. In other embodiments, the film is deposited at a deposition rate of from about 30 to 200 nanometers (nm) per minute.

The pressure in the reaction chamber during deposition typically ranges from about 0.01 to about 600 torr or from about 1 to 15 torr.

The film is preferably deposited to a thickness of 0.05 to 500 microns, although the thickness can be varied as required. The blanket film deposited on a non-patterned surface has excellent uniformity, with a variation in thickness of less than 3% over 1 standard deviation across the substrate with a reasonable edge exclusion, wherein e.g., a 5 mm outermost edge of the substrate is not included in the statistical calculation of uniformity.

In addition to the inventive OSG products, the present invention includes the process by which the products are made, methods of using the products and compounds and compositions useful for preparing the products. For example, a process for making an integrated circuit on a semiconductor device is disclosed in U.S. Pat. No. 6,583,049, which is herein incorporated by reference.

The dense organosilica films produced by the disclosed methods exhibit excellent resistance to plasma induced damage, particularly during etch and photoresist strip processes as is illustrated in greater detail in the examples that follow.

The dense organosilica films produced by the disclosed methods exhibit excellent mechanical properties for a given dielectric constant relative to dense organosilica films having the same dielectric constant but made from a precursor that is not 1-methyl-1-iso-propoxy-silacyclopentane or 1-methyl-1-iso-propoxy-silacyclobutane. The resulting organosilica film (as deposited) typically has a dielectric constant of from 2.70 to 3.20 in some embodiments, 2.80 to 3.10 in other embodiments, and 2.70 to 3.00 in still other embodiments, an elastic modulus of from 11 to 25 GPa, and an at. % carbon of from 12 to 31 as measured by XPS. In other embodiments, the resulting organosilica film has a dielectric constant of from 2.70 to 3.20, 2.80 to 3.10 in other embodiments, and 2.80 to 3.00 in still other embodiments, an elastic modulus of from 11 to 25 GPa, and an at. % carbon of from 12 to 31 as measured by XPS. In one embodiment, the resulting organosilica film has a dielectric constant of 3.20, an elastic modulus of about 25 GPa, and an at. % carbon of about 14 as measured by XPS.

The resultant dense organosilica films may also be subjected to a post treating process once deposited. Thus, the term “post-treating” as used herein denotes treating the film with energy (e.g., thermal, plasma, photon, electron, microwave, etc.) or chemicals to further enhance materials properties.

The conditions under which post-treating are conducted can vary greatly. For example, post-treating can be conducted under high pressure or under a vacuum ambient.

UV annealing is a preferred method conducted under the following conditions.

The environment can be inert (e.g., nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.) or reducing (dilute or concentrated hydrogen, hydrocarbons (saturated, unsaturated, linear or branched, aromatics), etc.). The pressure is preferably about 1 Torr to about 1000 Torr. However, a vacuum ambient is preferred for thermal annealing as well as any other post-treating means. The temperature is preferably 200-500° C., and the temperature ramp rate is from 0.1 to 100 deg ° C./min. The total UV annealing time is preferably from 0.01 min to 12 hours.

The invention will be illustrated in more detail with reference to the following Examples, but it should be understood that the invention is not deemed to be limited thereto.

### EXAMPLES

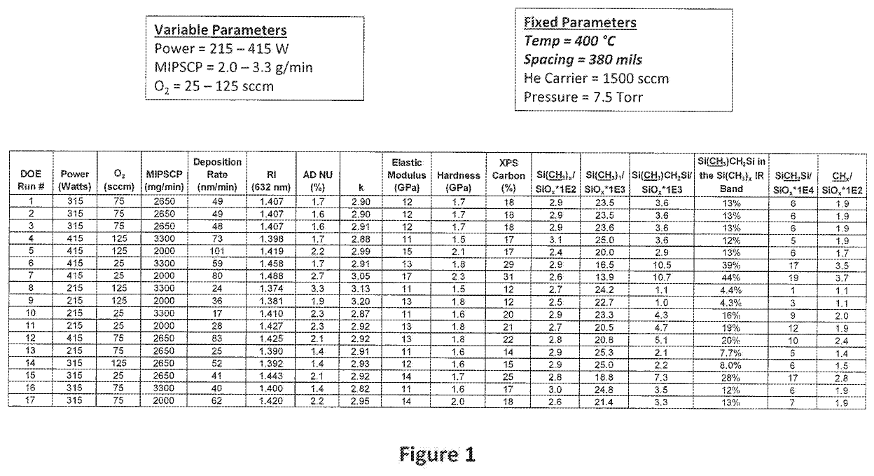

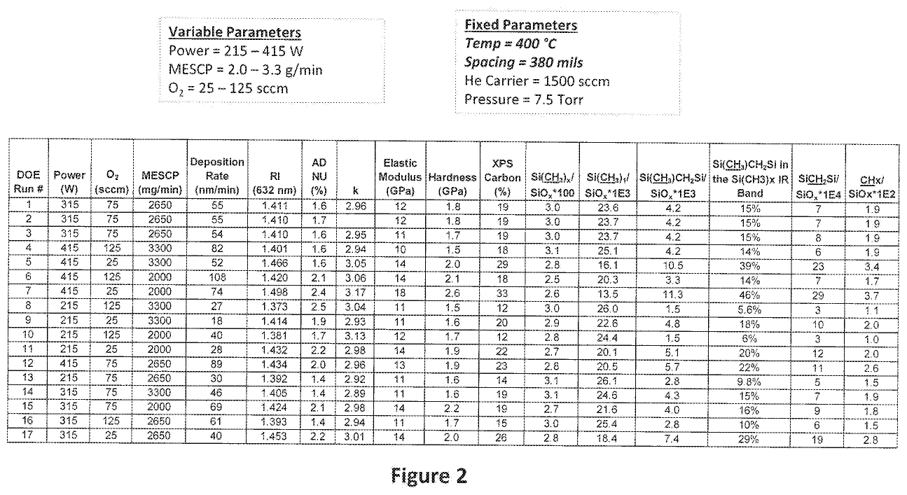

All experiments were performed on a 300 mm AMAT Producer SE, which deposits films on two wafers at the same time. Thus, the precursor and gas flow rates in FIGS. 2 to 6 correspond to the flow rates required to deposit films on two wafers at the same time. The RF power per wafer in FIGS. 1 to 4 is correct, as each wafer processing station has its own independent RF power supplies.

Comparative Example 1: A design of experiment (DOE) strategy was used to explore the range of low k films that could be deposited using 1-methyl-1-ethoxy-silacyclopentane (MESCAP) as a precursor. Process parameters that were fixed included: Temperature 400° C.; He Carrier flow 1500 sccm; Pressure 7.5 torr; Electrode spacing 380 mils. Independent variables were RF Power (13.56 MHz), O₂ Flow Rate (sccm), and MESCAP (mg/min). The ranges of the independent variables included: RF Power 215-415W; O₂ flow 25-125 sccm; MESCAP flow 2.0-3.3 g/min. The dependent variables that were modeled included deposition rate (nm/min), RI (632 nm), as deposited non-uniformity (%), dielectric constant, mechanical properties (elastic modulus and hardness, GPa), carbon content determined by XPS (atomic %), and the densities of various species within the SiOₓ network as determined by infrared spectroscopy. The latter included the total terminal silicon methyl density (Si(CH₃)ₓ/SiOₓ*1E2), the silicon methyl density attributable to Si(CH₃)₁ (Si(CH₃)₁/SiOₓ*1E3), the silicon methyl density attributable to Si(CH₃)CH₂Si (Si(CH₃)CH₂Si/SiOₓ*1E3), the disilylmethylene bridge density (SiCH₂Si/SiOₓ*1E4), and the percentage of Si(CH₃)CH₂Si that contributes to the total terminal silicon methyl density. A summary of the DOE results for the MESCAP based films is given in FIG. 2.

Example 2: A design of experiment (DOE) strategy was used to explore the range of low k films that could be deposited using 1-methyl-1-iso-propoxy-silacyclopentane (MIPSCP) as a precursor. Process parameters that were fixed included: Temperature 400° C.; He Carrier flow 1500 sccm; Pressure 7.5 torr; Electrode spacing 380 mils. The independent variables were RF Power (13.56 MHz), O₂ Flow Rate (sccm), and MIPSCP (mg/min). The ranges of the independent variables included: RF Power 215-415W; O₂ flow 25-125 sccm; MIPSCP flow 2.0-3.3 g/min. The dependent variables that were modeled included deposition rate (nm/min), RI (632 nm), as deposited non-uniformity (%), dielectric constant, mechanical properties (elastic modulus and hardness, GPa), carbon content determined by XPS (atomic %), and the densities of various species within the SiOₓ network as determined by infrared spectroscopy. The latter included the total terminal silicon methyl density (Si(CH₃)ₓ/SiOₓ*1E2), the silicon methyl density attributable to Si(CH₃)₁ (Si(CH₃)₁/SiOₓ*1E3), the silicon methyl density attributable to Si(CH₃)CH₂Si (Si(CH₃)CH₂Si/SiOₓ*1E3), the disilylmethylene bridge density (SiCH₂Si/SiOₓ*1E4), and the percentage of Si(CH₃)CH₂Si that contributes to the total terminal silicon methyl density. A summary of the DOE results for the MIPSCP based films is given in FIG. 1.

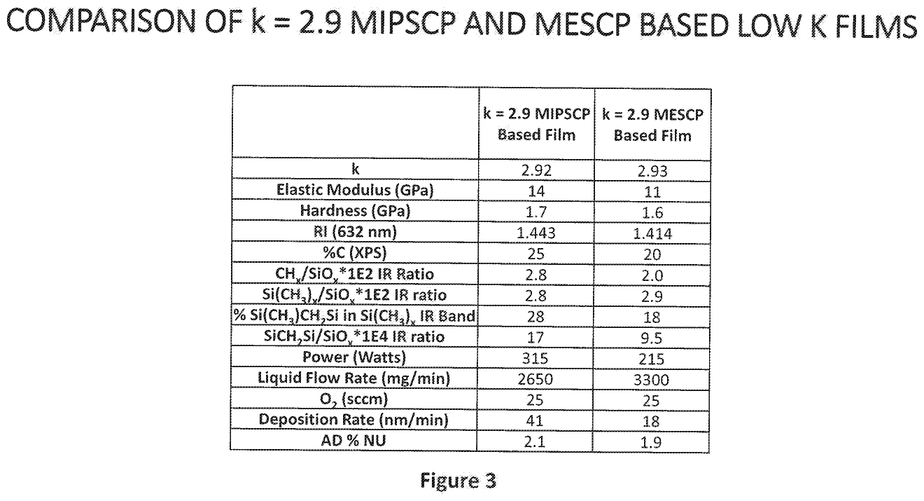

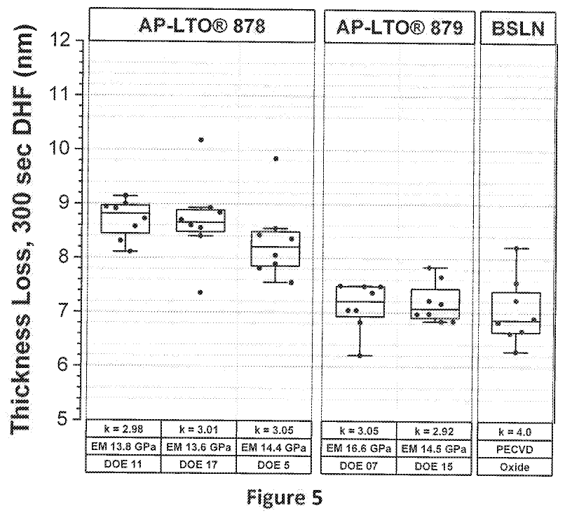

A careful examination of the dependent variables for films with the same value of the dielectric constant shows that the MIPSCP based films have a higher elastic modulus than equivalent MESCP based films. For example, FIG. 3 shows a comparison of two k=2.9 films. The elastic modulus of the MIPSCP based film is 3 GPa higher than that of the MESCP based film. FIG. 5 shows a comparison of a k=3.00 MIPSCP based low k film and a k=3.0 MESCP based low k film. As observed for the k=2.90 film comparison, the k=3.00 MIPSCP based film exhibits a higher elastic modulus than the MESCP based film. Thus, for low k films with a similar dielectric constant MIPSCP based films exhibit an unexpectedly high elastic modulus relative to MESCP based films, particularly as the only difference between the two molecules is the alkoxy group (iso-propoxy for MIPSCP vs ethoxy for MESCP). For both the k=2.90 and k=3.00 film comparisons, the MIPSCP based films exhibit a higher refractive index (RI), a greater XPS carbon content, and a lower total terminal silicon methyl density. Both the MIPSCP based and MESCP based films have a relatively high percentage of Si(CH₃)CH₂Si contributing to the total terminal silicon methyl density.

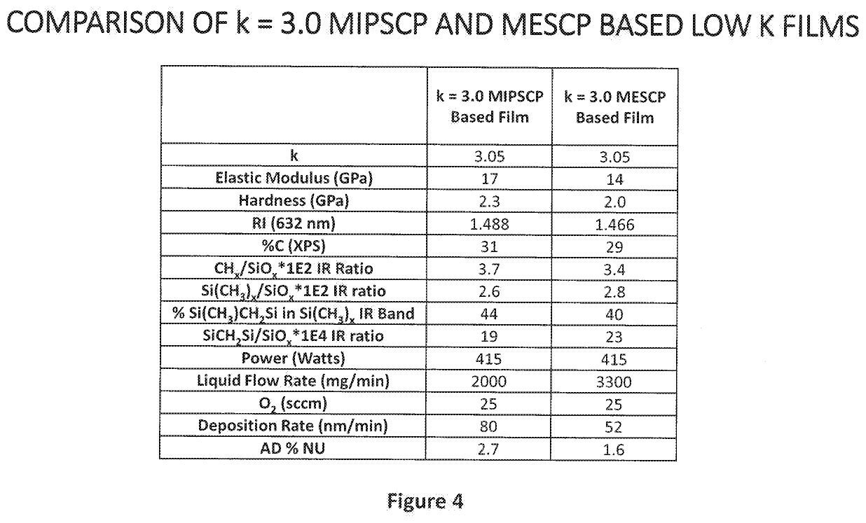

Importantly, the data reveals that for dense low k films, such as those summarized in FIGS. 1 and 2, a very small change in k can result in a large change in elastic modulus when MIPSCP is employed as the precursor to the film. For example, consider the two MIPSCP films in FIGS. 3 and 4. The k=2.92 film has an elastic modulus of 14 GPa, while the k=3.05 film has an elastic modulus of 17 GPa. Thus, increasing the dielectric constant by 0.13 results in an increase in the elastic modulus of 3 GPa.

Comparative Example 3: Prior art precursors like diethoxymethylsilane (DEMS®) provide limited film property tuning capabilities relative to carbon content and type under conditions of low or no O₂ flow. This was verified under the following test conditions: Power 400 Watts; Pressure 10 torr; Temperature 345° C.; Electrode spacing: 380 mils; He Carrier Flow: 750 sccm; DEMS® flow 850 mg/min. Oxygen was varied from 0-50 sccm. The results are shown in Table 1 below:

TABLE 1
Impact of O2 flow on DEMS ® based film properties

| O₂ Flow | | | EM | H | | Si(CH₃)₁ | Si—CH₂—Si |
|---|---|---|---|---|---|---|---|
| (sccm) | RI | k | GPa | GPa | % C | x1E⁻³ | x1E⁴ |
| 0 | 1.425 | 2.93 | 19 | 2.3 | 19 | 25.5 | 6 |
| 25 | 1.411 | 2.92 | 16 | 2.6 | 16 | 25.4 | 4 |
| 50 | 1.403 | 2.95 | 15 | 2.4 | 14 | 24.3 | 3 |

The data in Table 1 shows narrow tunability on the type and quantity of carbon in low-k films based on DEMS® at relatively low O₂ flows. The terminal methyl density within the film varied <5% as the O₂ flow was varied from 0-50. Total carbon content varied by 5% from 0 to 50 sccm O₂ flow. The bridging methylene density as determined by FTIR integrated peak ratio was low and varied from 6 to 3×1 E⁴.

Example 4: MIPSCP was found to have significantly more precise tuning capabilities depending on the flow rate of oxygen used during deposition. A variation on O₂ flow was evaluated at relatively low O₂ flow rates (32, 16 and 0 sccm) to determine the impact on dielectric constant, mechanical properties, quantity and type of carbon deposited in the film. The process conditions consisted of: Power 275 Watts; Pressure 7.5 torr; Temperature 390° C.; Electrode spacing: 380 mils; He Carrier Flow: 750 sccm; MIPSCP flow 850 mg/min. Oxygen was varied from 32 to 0 sccm. The results are shown in Table 2 below:

TABLE 2
Impact of O₂ flow on MIPSCP based film properties

| O₂ Flow | | | EM | H | | —Si(CH₃)₁ | Si—CH₂—Si |
|---|---|---|---|---|---|---|---|
| (sccm) | RI | k | GPa | GPa | % C | x1E⁻³ | x1E⁴ |
| 0 | 1.552 | 3.17 | 22 | 3.2 | 40 | 9.5 | 27 |
| 16 | 1.466 | 2.97 | 17 | 2.5 | 29 | 13.8 | 12 |
| 32 | 1.436 | 2.94 | 16 | 2.4 | 22 | 17.6 | 9 |

The data in Table 2 demonstrates the sensitivity of MIPSCP based low-k films to relatively small changes in O₂ flow. The RI, carbon content and type of carbon incorporated in the film vary significantly with O₂ flow. At zero O₂ flow the RI and bridging methylene density in the film, as indicated by the Si—CH₂—Si integrated absorbance relative to the SiOx absorbance in the FITR spectrum, increases significantly, as does the mechanical strength of the film. The terminal methyl density within the film varied by 85% as the O₂ flow was varied from 0-32 sccm. Total carbon content varied by 80% as the O₂ flow was varied from 0-32 sccm. The bridging methylene density as determined by FTIR integrated peak ratio was high and varied from 9-27×1 E⁴. The increase in methylene density causes an increase in dielectric constant proportional to the amount of carbon that is added to the film network, which increase is significantly higher than that obtained from DEMS® based films. This unexpected finding allows for precise tuning of the films carbon content and type to allow for optimization of film performance.

Example 5: The resistance to plasma induced damage is an important metric for low k films. FIG. 5 shows the thickness loss for select MIPSCP and MESCP based films, where the thickness loss is calculated as the difference in thickness between a plasma damaged coupon of a low k film before and after exposure to dilute HF (300:1) at room temperature for 300 seconds. The low k films were plasma damaged by exposing them to a capacitively coupled NH₃ based plasma for 15 seconds. This plasma damage step simulates an integration ashing step, where photoresist is removed from low k wafers using an NH₃ based ashing plasma. Using this methodology, the relative resistance to plasma induced damage of a low k film is taken as its measured thickness loss determined. For reference, the relative depth of plasma induced damage (i.e., thickness loss, 300 sec DHF) for a PECVD oxide is also shown.

The data in FIG. 5 show that the MIPSCP based films exhibit a smaller depth of plasma induced damage (DoPID) compared to the MESCP based films. Indeed, the DoPID of the MIPSCP based films is the same as that of a PECVD oxide. Of note is the k=2.92 MIPSCP based film, which exhibits a lower DoPID relative to the k=3.00 MESCP based films tested. This is unexpected, as typically the lower the dielectric constant the greater the DoPID. Importantly, MIPSCP based films exhibit an unexpectedly low DoPID relative to MESCP based films for films with the same dielectric constant.

Although illustrated and described above with reference to certain specific embodiments and examples, the present invention is nevertheless not intended to be limited to the details shown. Rather, various modifications may be made in the details within the scope and range of equivalents of the claims and without departing from the spirit of the invention. For example, it is recognized that the advantages of dense MIPSCP films described herein would also apply to porous MIPSCP based films. It is expressly intended, for example, that all ranges broadly recited in this document include within their scope all narrower ranges which fall within the broader ranges.

1. A method for making a dense organosilica film with improved mechanical properties, the method comprising the steps of:
providing a substrate within a reaction chamber;
introducing into the reaction chamber a gaseous composition comprising one or more selected from the group consisting of 1-methyl-1-iso-propoxy-silacyclopentane and 1-methyl-1-iso-propoxy-silacyclobutane; and
applying energy to the gaseous composition in the reaction chamber to induce reaction of the gaseous composition and thereby deposit an organosilica film on the substrate, wherein the organosilica film has a dielectric constant of from 2.80 to 3.00 and an elastic modulus of from 11 to 18 GPa.

2. The method of claim 1 wherein the gaseous composition is free of a hardening additive.

3. The method of claim 1 which is a chemical vapor deposition method.

4. The method of claim 1 which is a plasma enhanced chemical vapor deposition method.

5. The method of claim 1 wherein the gaseous composition comprises at least one oxidant selected from the group consisting of O₂, N₂O, NO, NO₂, CO₂, water, H₂O₂, ozone, and combinations thereof.

6. The method of claim wherein the gaseous composition comprises O₂ and is introduced during reaction of the gaseous composition at a rate of no greater than 32 sccm.

7. The method of claim 1 wherein the gaseous composition does not comprise an oxidant.

8. The method of claim 1 wherein the reaction chamber in the applying step comprises at least one gas selected from the group consisting of He, Ar, N₂, Kr, Xe, CO₂, and CO.

9. The method of claim 1 wherein the organosilica film has a refractive index (RI) of from 1.44 to 1.49 at 632 nm and an at. % carbon as measured by XPS of from 25% to 31%.

10. The method of claim 1 wherein the organosilica film is deposited at a rate of from 41 nm/min to 80 nm/min.

11. The method of claim 8 wherein the organosilica film has a SiCH₂Si/SiOₓ*1E⁴ IR ratio of from 17 to 19.

12. A method for making a dense organosilica film with improved mechanical properties, the method comprising the steps of:
providing a substrate within a reaction chamber;
introducing into the reaction chamber a gaseous composition comprising one or more selected from the group consisting of 1-methyl-1-iso-propoxy-silacyclopentane and 1-methyl-1-iso-propoxy-silacyclobutane; and
applying energy to the gaseous composition in the reaction chamber to induce reaction of the gaseous composition and thereby deposit an organosilica film on the substrate, wherein the organosilica film has a dielectric constant of from 2.80 to 3.10, an elastic modulus of from 11 to 20 GPa, and an at. % carbon of from 12 to 31 as measured by XPS.

13. The method of claim 11 wherein the gaseous composition is free of a hardening additive.

14. The method of claim 11 which is a chemical vapor deposition method.

15. The method of claim 11 which is a plasma enhanced chemical vapor deposition method.

16. The method of claim 11 wherein the gaseous composition comprises at least one oxidant selected from the group consisting of O₂, N₂O, NO, NO₂, CO₂, water, H₂O₂, ozone, and combinations thereof.

17. The method of claim 16 wherein the gaseous composition comprises O₂ and is introduced during reaction of the gaseous composition at a rate of no greater than 32 sccm.

18. The method of claim 11 wherein the gaseous composition does not comprise an oxidant.

19. The method of claim 11 wherein the reaction chamber in the applying step comprises at least one gas selected from the group consisting of He, Ar, N₂, Kr, Xe, CO₂, and CO.

20. The method of claim 11 wherein the organosilica film has a refractive index (RI) of from 1.443 to 1.488 at 632 nm.

21. The method of claim 11 wherein the organosilica film is deposited at a rate of from 41 nm/min to 80 nm/min.

22. The method of claim 18 wherein the organosilica film has a SiCH₂Si/SiOₓ*1E⁴ IR ratio of from 17 to 19.

23. A method for making a dense organosilica film with improved mechanical properties, the method comprising the steps of:
providing a substrate within a reaction chamber;
introducing into the reaction chamber a gaseous composition comprising 1-methyl-1-iso-propoxy-silacyclopentane or 1-methyl-1-iso-propoxy-silacyclobutane; and
applying energy to the gaseous composition in the reaction chamber to induce reaction of the gaseous composition and thereby deposit an organosilica film on the substrate, wherein the organosilica film has a dielectric constant of from 2.70 to 3.20 and an elastic modulus of from 11 to 25 GPa.
